(19) United States
(12) Patent Application Publication
(10) Pub. No.: US 2025/0210365 A1
(43) Pub. Date: Jun. 26, 2025

(54) COMPONENT HAVING AT LEAST ONE FEATURE FORMED BY APPLYING AT LEAST TWO LAYERS OF DIFFERENT MATERIALS ON A SUBSTRATE

(71) Applicant: Quantinuum LLC, Broomfield, CO (US)

(72) Inventors: Adam Jay OLLANIK, Boulder, CO (US); Rezlind BUSHATI, Broomfield, CO (US); Amit AGRAWAL, Gaithersburg, MD (US); Henri LEZEC, Gaithersburg, MD (US); Wenqi ZHU, Gaithersburg, MD (US)

(21) Appl. No.: 18/940,548

(22) Filed: Nov. 7, 2024

Related U.S. Application Data
(60) Provisional application No. 63/613,168, filed on Dec. 21, 2023.

(51) Int. Cl. H01L 21/308; C23C 14/04; C23C 16/455; H01L 21/027

(52) U.S. Cl. CPC H01L 21/3081; C23C 14/042; C23C 16/45553; H01L 21/0274; H01L 21/3086

(57) ABSTRACT

A method of forming at least one feature on a substrate of a component for an electrical and/or optical device is provided. The method may include applying a masking layer on the substrate. The masking layer may define at least one cavity that is positioned between portions of the masking layer. The method may include applying a first layer of a first material on the masking layer and applying a second layer of a second material on the first layer. The method may include removing a first portion of the first layer and a first portion of the second layer with an etching process.

### CROSS-REFERENCE TO RELATED APPLICATIONS

This application claims priority to and the benefit of U.S. Provisional Application No. 63/613,168, filed Dec. 21, 2023, the contents of which are hereby incorporated by reference in its entirety.

### STATEMENT REGARDING FEDERALLY SPONSORED RESEARCH

This invention was made with United States Government support from the National Institute of Standards and Technology (NIST), an agency of the United States Department of Commerce, under Collaborative Research and Development Agreement CN-21-0096. The Government has certain rights in this invention.

### TECHNICAL FIELD

The present application relates generally to fabrication of components of an electrical and/or optical device that includes at least one feature formed on a substrate of the component. More specifically, the present application relates to forming the at least one feature by applying at least two layers of different materials on the substrate of the component.

### BACKGROUND

Components of electrical and/or optical devices often include features that are formed on a substrate, such as a semiconductor wafer. Conventional methods of forming these features may result in a resolution of the features or an aspect ratio of the features that is lower than desired. Also, conventional methods of forming these features may result in a feature that does not achieve a desired refractive index for at least a region of the feature.

The inventors have identified these and numerous other deficiencies and problems with the existing technologies in this field. Through applied effort, ingenuity, and innovation, many of these identified deficiencies and problems have been solved by developing solutions that are structured in accordance with the embodiments of the present disclosure, many examples of which are described in detail herein.

### BRIEF SUMMARY

In general, embodiments of the present disclosure provided herein include method for fabricating improved components of electrical and/or optical devices that include at least one feature formed on a substrate of the component.

In various aspects, a method of forming at least one feature on a substrate of a component for an electrical and/or optical device is provided. The method may include forming at least one cavity in a masking layer on the substrate. The at least one cavity may be positioned between portions of the masking layer. The method may include applying a first layer of a first material on the masking layer. The first layer may be deposited on a bottom of the at least one cavity. The method may include applying a second layer of a second material on the first layer. The second layer may be deposited on the first layer within the at least on cavity. The method may include removing a first portion of the first layer and a first portion of the second layer with an etching process. The first portion of the first layer and the first portion of the second layer may be disposed outside of the at least one cavity.

In various examples, the method may include removing the masking layer with an etching process.

In various examples, the method may include applying the first layer of the first material on the masking layer and on a portion of the substrate.

In various examples, at least a second portion of the first layer and a second portion of the second layer is positioned within the cavity after removing the first portion of the first layer and the first portion of the second layer with the etching process.

In various examples, the method may include removing a vertical portion of the second portion of the second layer that is positioned within the cavity after removing the first portion of the first layer and the first portion of the second layer with the etching process.

In various examples, at least a lateral portion of the second portion of the second layer is positioned on the first layer after removing the vertical portion of the second portion of the second layer.

In various examples, applying the first layer of the first material on the masking layer and applying the second layer of the second material on the masking layer is performed with a chemical vapor deposition (CVD) process.

In various examples, the CVD process is an atomic layer deposition (ALD) process.

In various examples, applying the first layer of the first material on the masking layer and applying the second layer of the second material on the masking layer is performed with a physical vapor deposition (PVD) process.

In various examples, each of the at least one cavity defines a height (H) and a width (W), wherein a ratio (H:W) between the height (H) and the width (W) of each of the at least one cavity is at least 1:1.

In various examples, the method may include forming a plurality of cavities in the masking layer on the substrate, and wherein a width (W) of at least one of the plurality of cavities is different than a width (W) of another one of the plurality of cavities.

In various examples, the first layer has a first thickness and the second layer has a second thickness, and wherein the first thickness is different than the second thickness by at least five percent.

In various examples, the method may include applying a third layer of a third material on the second layer.

In various examples, the method may include applying a fourth layer of a fourth material on the third layer.

In various examples, the method may include applying a third layer of the first material on the second layer and applying a fourth layer of the second material on the third layer. The first layer may have a first thickness, the second layer may have a second thickness, the third layer may have a third thickness, and the fourth layer may have a fourth thickness.

In various examples, the first thickness, the second thickness, the third thickness, and the fourth thickness are each different than the other thicknesses by at least five percent.

In various examples, the first thickness and the third thickness are within five percent of each other, the second thickness and the fourth thickness are within five percent of each other, and
the first thickness is different than the second thickness by at least five percent.

In various examples, the method may include applying a third layer of the first material or a third material on the second layer, applying a fourth layer of the second material or a fourth material on the third layer. The first layer, the second layer, the third layer, and the fourth layer may define a refractive index profile that either decreases or increases as the layers are applied.

In various examples, the first layer is a first contact layer that comprises an optically transparent and electrically conductive material.

In various examples, at least one cavity has a chiral shape.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the present disclosure in any way. It will be appreciated that the scope of the present disclosure encompasses many potential embodiments in addition to those here summarized, some of which will be further described below. Other features, aspects, and advantages of the subject matter will become apparent from the description, the drawings, and the claims.

### BRIEF DESCRIPTION OF THE DRAWINGS

Having thus described certain example embodiments of the present disclosure in general terms above, non-limiting and non-exhaustive embodiments of the subject disclosure are described with reference to the following figures, which are not necessarily drawn to scale and wherein like reference numerals refer to like parts throughout the various views unless otherwise specified. The components illustrated in the figures may or may not be present in certain embodiments described herein. Some embodiments may include fewer (or more) components than those shown in the figures.

FIG. 1 provides a cross-sectional, side view of at least a portion of a component during a manufacturing stage, in accordance with an example embodiment.

FIG. 2A provides a top view of at least a portion of a component during a manufacturing stage, in accordance with an example embodiment.

FIG. 2B provides a top view of at least a portion of a component during a manufacturing stage, in accordance with an example embodiment.

FIG. 2C provides a top view of at least a portion of a component during a manufacturing stage, in accordance with an example embodiment.

FIG. 2D provides a top view of at least a portion of a component during a manufacturing stage, in accordance with an example embodiment.

FIG. 3 provides a cross-sectional, side view of at least a portion of a component during a manufacturing stage, in accordance with an example embodiment.

FIG. 4 provides a cross-sectional, side view of at least a portion of a component during a manufacturing stage, in accordance with an example embodiment.

FIG. 5 provides a cross-sectional, side view of at least a portion of a component during a manufacturing stage, in accordance with an example embodiment.

FIG. 6 provides a cross-sectional, side view of at least a portion of a component during a manufacturing stage, in accordance with an example embodiment.

FIG. 7 provides a cross-sectional, side view of at least a portion of a component during a manufacturing stage, in accordance with an example embodiment.

FIG. 8A provides a cross-sectional, side view of at least a portion of a component during a manufacturing stage, in accordance with an example embodiment.

FIG. 8B provides a cross-sectional, side view of at least a portion of a component during a manufacturing stage, in accordance with an example embodiment.

FIG. 9 provides a cross-sectional, side view of at least a portion of a component during a manufacturing stage, in accordance with an example embodiment.

FIG. 10 provides a cross-sectional, side view of at least a portion of a component during a manufacturing stage, in accordance with an example embodiment.

FIG. 11 provides a cross-sectional, side view of at least a portion of a component during a manufacturing stage, in accordance with an example embodiment.

FIG. 12 provides a flow chart for a method of forming at least one feature on a substrate of a component, in accordance with an example embodiment.

FIG. 13A provides a top view of at least a portion of the component of FIG. 8B during a subsequent manufacturing stage, in accordance with an example embodiment.

FIG. 13B provides a top view of at least a portion of a component, in accordance with an example embodiment.

FIG. 14A provides a top view of at least a portion of a component during a manufacturing stage, in accordance with an example embodiment.

FIGS. 15A-16C provides cross-sectional side views of the component of FIG. 14A during various manufacturing stages, in accordance with an example embodiment.

FIG. 17A provides a cross-sectional, side view of at least a portion of a component during a manufacturing stage, in accordance with an example embodiment.

FIG. 17B provides a cross-sectional, side view of at the component of FIG. 17A during a subsequent manufacturing stage, in accordance with an example embodiment.

FIG. 18A provides a cross-sectional, side view of at least a portion of a component during a manufacturing stage, in accordance with an example embodiment.

FIG. 18B provides a cross-sectional, side view of at the component of FIG. 17A during a subsequent manufacturing stage, in accordance with an example embodiment.

### DETAILED DESCRIPTION

One or more embodiments are now more fully described with reference to the accompanying drawings, wherein like reference numerals are used to refer to like elements throughout and in which some, but not all embodiments of the inventions are shown. In the following description, for purposes of explanation, numerous specific details are set forth in order to provide a thorough understanding of the various embodiments. It is evident, however, that the various embodiments can be practiced without these specific details. It should be understood that some, but not all embodiments are shown and described herein. Indeed, the embodiments may be embodied in many different forms, and accordingly this disclosure should not be construed as limited to the embodiments set forth herein. Rather, these embodiments are provided so that this disclosure will satisfy applicable legal requirements.

As used herein, the term “exemplary” means serving as an example, instance, or illustration. Any aspect or design described herein as “exemplary” is not necessarily to be construed as preferred or advantageous over other aspects or designs. Rather, use of the word exemplary is intended to present concepts in a concrete fashion. In addition, while a particular feature may be disclosed with respect to only one of several implementations, such feature may be combined with one or more other features of the other implementations as may be desired and advantageous for any given or particular application. Furthermore, to the extent that the terms “includes” and “including” and variants thereof are used in either the detailed description or the claims, these terms are intended to be inclusive in a manner similar to the term “comprising.”

As used herein, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

As used herein, the term “positioned directly on” refers to a first component being positioned on a second component such that they make contact. Similarly, as used herein, the term “positioned directly between” refers to a first component being positioned between a second component and a third component such that the first component makes contact with both the second component and the third component. In contrast, a first component that is “positioned between” a second component and a third component may or may not have contact with the second component and the third component. Additionally, a first component that is “positioned between” a second component and a third component is positioned such that there may be other intervening components between the second component and the third component other than the first component.

As used herein, terms of approximation, such as “approximately,” “substantially,” or “about,” refer to being within manufacturing or engineering tolerances. For example, terms of approximation may refer to being withing a five percent margin of error.

Various embodiments provide methods for fabricating components of electrical and/or optical devices. In various embodiments, the fabrication method includes lithographically, for example, defining a mold and filling the mold with multiple deposition layers.

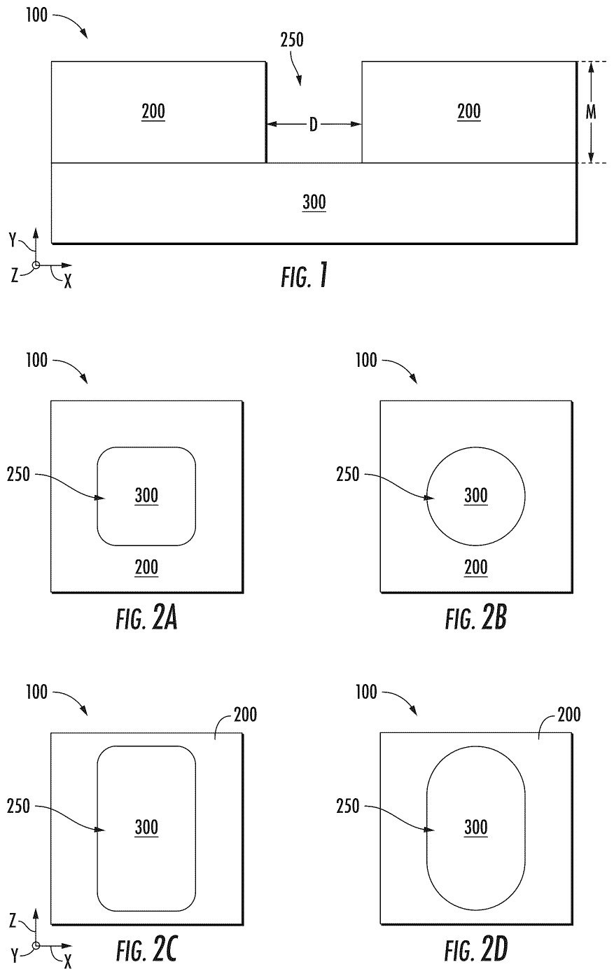

Referring now to FIG. 1, a cross-sectional, side view of at least a portion of a component 100 during a manufacturing stage is provided, in accordance with an example embodiment. The component 100 can be a component 100 of an electrical and/or optical device (not depicted). The component 100 can define an X direction, a Y direction that is orthogonal to the X direction, and a Z direction that is orthogonal to the X direction and the Y direction. The X direction and the Y direction can be lateral directions and the Z direction can be a vertical direction relative to the component 100. In various examples, the electrical and/or optical device is a quantum information device, such as a quantum computer, an ion trap for a quantum computer, a clock, or various other devices that are configured for sensing, networking, cryptography, etc.

The component 100 may be a photonic component or an integrated optical component. For example, the component 100 can be a photonic coupling element, which may be a device that couples light from a guided mode to a free space propagating mode. The component 100 can be a metasurface of an optical device. For example, the component 100 can be a lens, a quarter or half waveplate metasurface, a spatial beam shaping metasurface, a beam directing metasurface, a lens for an image sensor, a laser beam splitter, or a color filter. In various examples, the component 100 can be a diffractive optic-phase-array or a hologram (e.g., lens hologram, graded arrays for beam direction, or spatial beam shaping holograms). In yet other examples, the component 100 can be a ring resonator, a power modulator, a waveguide, an input taper, a splitter (e.g., multi-mode interference (MMI), or y-branch), or a directional coupler. In yet other examples, the component 100 can be phonetic component, such as a metasurface for an antenna or a sound absorbing device.

The component 100 can be manufactured by applying and/or depositing a masking layer 200 on a substrate 300. The substrate 300 can be a wafer that includes silicon (Si), such as silicon dioxide (SiO2) or silicon nitride (Si3N4), germanium (Ge), or a combination thereof. The masking layer 200 can include any material that can be subsequently removed, such as removed by etching, such as removed by a selective etch process. For example, the masking layer 200 can include aluminum (Al), Si, silicon carbide (SiC), Si3N4, SiO2, copper (Cu), or a combination thereof. In various examples, the masking layer 200 includes any electron beam lithography resist material and/or a photolithography resist material. The masking layer 200 can be applied and/or deposited on the substrate 300 and one or more cavities may be formed therein using a lithography process, such as a photolithography process or an electron beam lithography process.

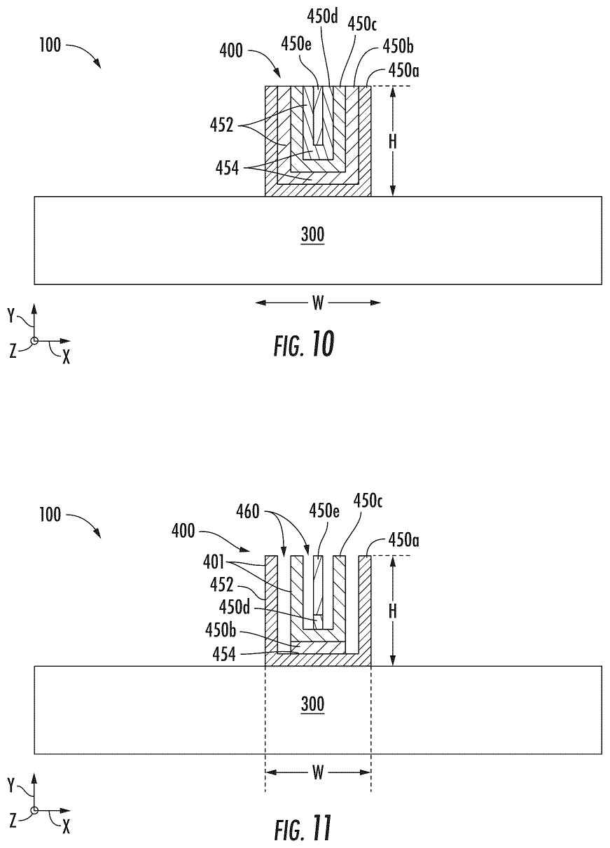

The masking layer 200 can have a masking thickness M. As will become apparent with the present disclosure, the masking thickness M can substantially correspond (e.g., within a five percent difference) to a height H (FIGS. 10, 11) of at least one feature 400 of the component 100. The masking layer 200 can define at least one cavity 250, which may be at least one void formed in the masking layer 200. For example, at least one cavity 250 may be lithographically formed within the masking layer 200. For example, each cavity 250 can be positioned within the masking layer 200 or between portions of the masking layer 200. Each cavity 250 can be defined by walls of the masking layer 200 that extend away from the substrate 300 and by a portion of the substrate 300 that is defined by the cavity 250. Each cavity 250 can define a distance D that is a minimum distance between the walls of the masking layer 200 that define each cavity 250. In various examples, at least one cavity 250 has a distance D that is different than a distance D of another cavity 250. As will also become apparent with the present disclosure, the distance D of each cavity 250 may substantially correspond to a width W (FIGS. 10, 11) of at least one feature 400 of the component 100. The width W and/or the distance D may be a “critical dimension”, a term of art in lithography, which may be measured at a specific height above the substrate.

In various examples, a ratio (M:D) between the masking thickness M and the distance D defined by at least one cavity 250 is at least 1:1. The ratio (M:D) between the masking thickness M and the distance D defined by at least one cavity 250 may substantially correspond to a ratio (H:W) between a height H of at least one feature 400 and a width W of the at least one feature 400 of the component 100. In various examples, the masking thickness M and the corresponding height H of the at least one feature 400 can be less than three nanometers (nm). In various examples, the masking thickness M and the corresponding height H of the at least one feature 400 can be at least three nm, such as at least ten nm, such as at least fifty nm, such as at least one hundred nm, such as at least three hundred nm.

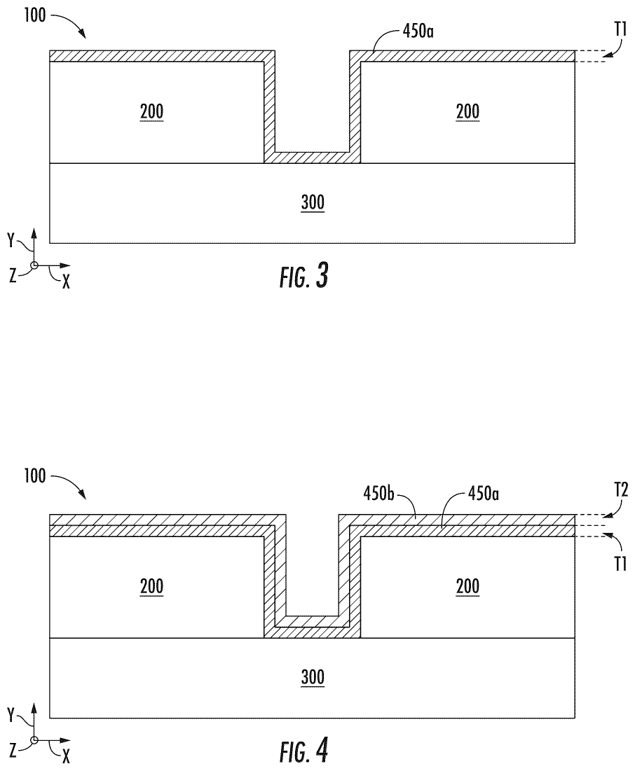

Referring now to FIGS. 2A-2D, top views of at least a portion of a component 100 during a manufacturing stage is provided, in accordance with various example embodiments. Each cavity 250 can have any shape. For example, the shape of at least one cavity 250 can be substantially square, as depicted in FIG. 2A, substantially circular, as depicted in FIG. 2B, substantially rectangular, as depicted in FIG. 2C, or substantially ovular, as depicted in FIG. 2D. In various example, the shape of at least one cavity 250 can be irregular. For example, the at least one cavity 250 can have sides of different lengths and/or angles of different sizes. Each cavity 250 can have the same shape or at least one cavity 250 can have a different shape than others.

Referring now to FIG. 3, a cross-sectional, side view of at least a portion of a component 100 during a manufacturing stage is provided, in accordance with an example embodiment. The component 100 can be manufactured by applying a first layer 450a of a first material on the masking layer 200. The first layer 450a may also be applied on a portion of the substrate 300. For example, the first layer 450a may be applied to the at least one portion of the substrate 300 that partially defines the at least one cavity 250. In various examples, the first material is a dielectric material. In various examples, the first material is a metallic material. In various examples, the first material is a semiconductor material.

The first layer 450a can be applied on the masking layer 200 with a chemical vapor deposition (CVD) process. For example, the CVD process can be an atomic layer deposition (ALD) process. The ALD process is a deposition technique that may deposit highly conformal coatings on substrates with a controlled and uniform thickness. The ALD process can include adding a first precursor to a reaction chamber that contains the substrate 300 and/or structure array to be coated. After the first precursor is absorbed by the substrate 300 and/or structure array, the first precursor can be removed from the reaction chamber and a second precursor can be added to the chamber to react with the first precursor, which may create a layer on the surface of the substrate 300. The second precursor can then be removed from the reaction chamber and the process can be repeated until a desired thickness T1 of the first layer 450a is achieved. In an example embodiment, the desired thickness T1 is less than ten nanometers (nm) or less than fifty nanometers (nm).

In various examples, the first layer 450a can be applied on the masking layer 200 with a physical vapor deposition (PVD) process, such as sputtering and evaporation. The PVD process is a process where a solid material is vaporized in a vacuum and deposited onto a substrate 300. In various examples, the first layer 450a can be applied on the masking layer 200 with a flux-controlled CVD process. In various examples, the first layer 450a can be applied on the masking layer 200 with an electroplating process.

Referring now to FIG. 4, a cross-sectional, side view of at least a portion of a component 100 during a manufacturing stage is provided, in accordance with an example embodiment. The component 100 can be manufactured by applying a second layer 450b of a second material on the first layer 450a of the first material. The second layer 450b of the second material and any additional layers 450 can be applied on the first layer 450a of the first material with a CVD process, such as an ALD process or a flux-controlled CVD process, a PVD process, such as sputtering and evaporation, or an electroplating process. The first layer 450a and any subsequent layers, such as the second layer 450b, may be applied with any conformal deposition process such that the layers 450 have a uniform thickness. The second material and any subsequent layers can be a dielectric material, a semiconductor material, a metallic material, or a combination thereof.

The second material of the second layer 450b can be different than the first material of the first layer 450a. In various examples, the first material of the first layer 450a has a different material property than the second material of the second layer. For example, the first material of the first layer 450a may have a different acoustic or optical refractive index than the second material of the second layer. In various examples, the first material of the first layer 450a has a first refractive index (n1) and the second material of the second layer 450b has a second refractive index (n2). In various examples, the first refractive index (n1) of the first layer 450a is different than the second refractive index (n2) of the second layer 450b. For example, the percent difference between the first refractive index (n1) and the second refractive index (n2) may be greater than 0.5 percent, where the percent difference between the first refractive index (n1) and the second refractive index (n2) is calculated by the formula (|n1−n2|)/((n1+n2)/2)*100. In various examples, the percent difference between the first refractive index (n1) and the second refractive index (n2) is at least 0.5 percent and up to eight hundred percent, such as at least 0.5 percent and up to six hundred percent, such as at least five percent and up to five hundred percent, such as at least ten percent and up to four hundred percent. In various examples, the first refractive index (n1) and the second refractive index (n2) are the real part of the refractive index.

The first layer 450a can have a first thickness T1 and the second layer 450b can have a second thickness T2. In various examples, the first thickness T1 and the second thickness T2 are the same or substantially the same (e.g., within five percent of each other). In various examples, the first thickness T1 and the second thickness T2 are different. For example, the percent difference between the first thickness (T1) and the second thickness (T2) may be greater than five percent, where the percent difference between the first thickness (T1) and the second thickness (T2) is calculated by the formula (|T1−T2|)/((T1+T2)/2)*100. In various examples, the percent difference between the first thickness (T1) and the second thickness (T2) is at least five percent and up to one thousand percent, such as at least five percent and up to five hundred percent, such as at least fifty percent and up to four hundred percent, such as at least one hundred percent and up to three hundred percent.

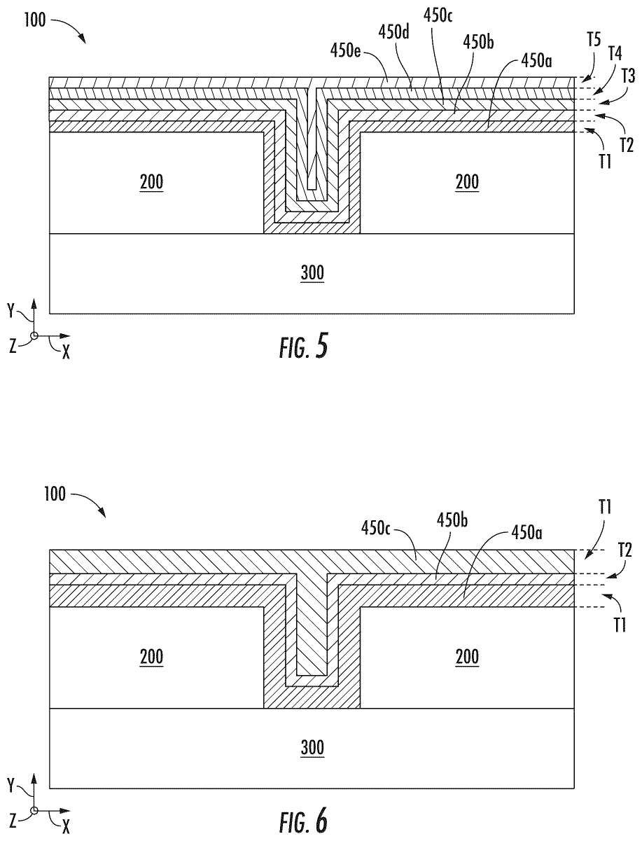

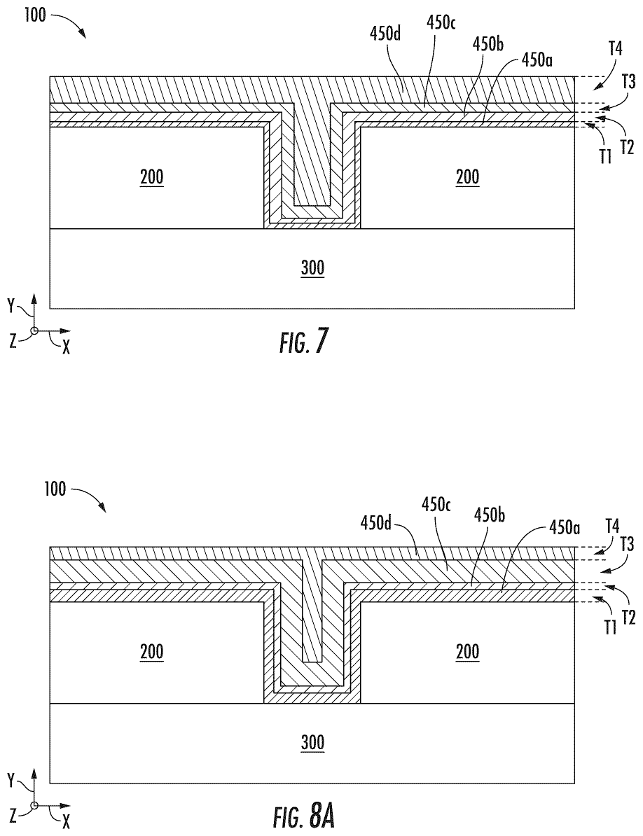

Referring now to FIG. 5, a cross-sectional, side view of at least a portion of a component 100 during a manufacturing stage is provided, in accordance with an example embodiment. The component 100 can be manufactured by applying three or more layers 450 of at least two different materials on the substrate 300. For example, at least three layers 450 and up to fifty layers 450, such as at least three layers 450 and up to twenty layers 450, such as at least three layers 450 and up to ten layers 450, such as at least four layers 450 and up to eight layers 450 of at least two materials can be applied to the substrate 300 to manufacture the component 100. Each of the three or more layers 450 can be a layer 450 of the first material, the second material, or another material, such as a third material, a fourth material, or a fifth material.

In various examples, the materials of the layers 450 alternate. For example, odd layers 450 (e.g., the first layer 450a, the third layer 450c, and the fifth layers 450e) can be of a first material and even layers 450 (e.g., the second layer 450b and the fourth layer 450d) can be of a second material. In various examples, the component 100 includes at least three layers 450 of three different materials that alternate. For example, a first layer 450a and a fourth layer 450d can be of a first material, a second layer 450b and a fifth layer 450e can be of a second material, and a third layer 450c and a sixth layer 450 can be of a third material.

In various examples, at least one layer 450 of a third material is applied such that the at least one layer 450 of the third material is positioned between a layer 450 of a first material and a layer 450 of a second material. For example, a first layer 450a of a first material can be applied on the substrate 300, a second layer 450b of a second material can be applied to the first layer 450a, a third layer 450c of a third material can be applied to the second layer 450b, and a fourth layer 450d of a first material or a second material can be applied to the third layer 450c. One or more additional layers 450 can then be applied to the fourth layer 450d.

In various examples, the materials applied on the substrate 300 are chosen to define a refractive index profile, such as a gradient refractive index profile, that either decreases or increases as the layers 450 are applied. For example, a first material of a first layer 450a applied to the substrate 300 can have a first refractive index n1, a second material of a second layer 450b applied to the substrate 300 can have a second refractive index n2, a third material of a third layer 450c applied to the substrate 300 can have a third refractive index n3, and so forth. The first refractive index n1 can be greater than the second refractive index n2, which can be greater than the third refractive index n3, and so forth. In various examples, the first refractive index n1 can be less than the second refractive index n2, which can be less than the third refractive index n3. In various examples, the refractive indexes n1, n2, n3 may be altered by adjusting the thickness of the respective layer 450.

Referring now to FIGS. 6-8, cross-sectional, side views of at least a portion of a component 100 during a manufacturing stage are provided, in accordance with various example embodiments. Different combinations of different thicknesses are contemplated. For example, and as depicted in FIG. 6, the thickness of the layers 450 can alternate such that odd layers 450 (e.g., the first layer 450a and the third layer 450c) can have a first thickness T1 and even layers 450 (e.g., the second layer 450b) can have a second thickness T2. The first thickness T1 can be greater than the second thickness T2. In various examples, the first thickness T1 is less than the second thickness T2.

At least one of the layers 450 could be less than 10 nanometers (nm) thick, such as less than 5 nm thick. In various examples, at least one of the layers 450 could be at least 10 nm thick, such as at least 10 nm and up to 500 nm thick, such as at least 10 nm and up to 300 nm thick, such as at least 10 nm and up to 100 nm thick. In various examples, at least one of the layers 450 could be at least 100 nm thick and up to 500 nm thick, such as at least 300 nm thick and up to 500 nm thick. In various examples, at least one of the layers 450 is less than 10 nm thick and another one of the layers 450 is at least 10 nm thick. In various examples, at least one of the layers 450 is less than 50 nm thick and another one of the layers 450 is at least 50 nm thick.

In various examples, and as depicted in FIG. 7, the layers 450 can define a gradient thickness that either decreases or increases as the layers 450 are applied. For example, the first layer 450a can have a first thickness T1, the second layer 450b can have a second thickness T2, the third layer 450c can have a third thickness T3, and the fourth layer 450d can have a fourth thickness T4. As depicted in FIG. 7, the layers 450 can define an increasing gradient thickness such that the first thickness T1 can be less than the second thickness T2, which can be less than the third thickness T3, which can be less than the fourth thickness T4. The layers 450 can define a decreasing gradient thickness such that the thickness of the layers 450 decrease as they are sequentially applied.

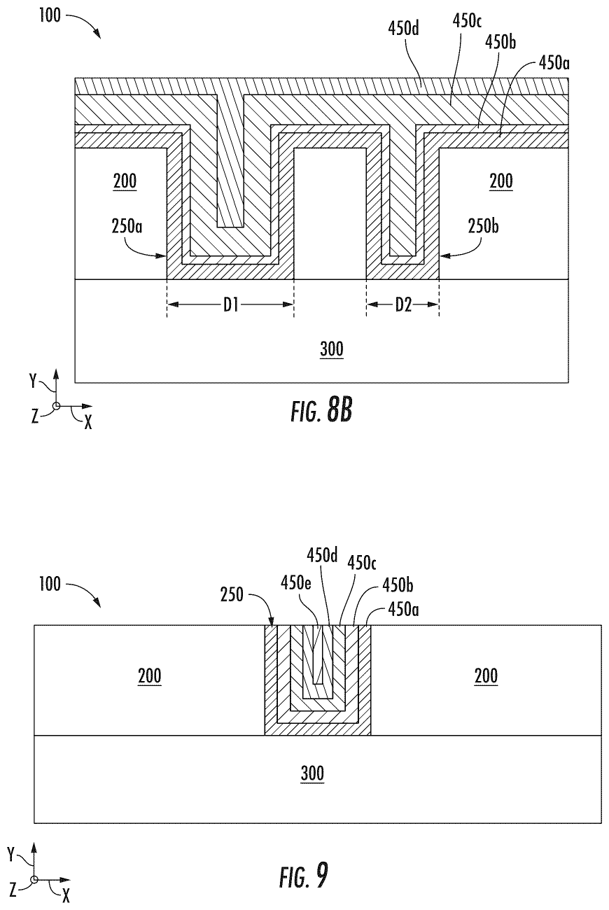

In various examples, and as depicted in FIG. 8A, the layers 450 are neither alternating nor do they define a gradient thickness. For example, and as depicted in FIG. 8A, the first thickness T1 of the first layer 450a can be greater than the second thickness T2 of the second layer 450b, which can be less than the third thickness T3 of the third layer 450c, which can be greater than the fourth thickness T4 of the fourth layer 450d. The first thickness T1, the second thickness T2, the third thickness T3, and the fourth thickness T4 can each be different than the other thicknesses by at least five percent.

In various examples, the thickness of each layer 450 and the type of material for each layer 450 can be tailored. For example, a predetermined refractive index for at least a region of the plurality of layers 450 may be desired. To achieve this desired refractive index for at least the region, two different materials of a different refractive index that is not the same as the desired refractive index may be used for at least two of the layers 450. To achieve the desired refractive index, the thickness of each of the at least two layers 450 can be chosen so that the average refractive index of the at least two layers 450 is at least substantially equal to the desired refractive index.

Referring now to FIG. 8B, at least one cavity 250a can define a distance D1 that is different than a distance D2 of another cavity 250b (i.e., at least one cavity 250a can have a different size than another cavity 250b) and/or at least one cavity 250 can define a different shape than at least another cavity 250. As such, because each layer 450 can have a uniform thickness, at least one cavity 250b may fill with at least one layer 450 prior to at least another cavity 250a. More specifically, a cavity 250b that defines a smaller distance D2 than another cavity 250a that defines a larger distance D1 will become filled prior to the cavity 250a that has the larger distance D1. Therefore, any layers 450 applied after the cavity 250b that defines the smaller distance D2 is filled, will not be applied within the cavity 250b that defines the smaller distance D. Accordingly, the layers 450 that are positioned within the cavity 250a that defines the larger distance D1 may be different than the layers 450 that are positioned within the cavity 250b that defines the smaller distance D2. For example, the cavity 250a that defines the larger distance D1 may have layers 450a-450d positioned within it, whereas the cavity 250b that defines the smaller distance D2 may only have layers 450a-450c positioned within it. As such, this may enable a component 100 that has features with differing material properties (e.g., differing material, differing size/shape of features) and/or cross-sectional material profiles to be patterned on a substrate 300 using the disclosed layering methods. For example, layer 450d may be comprised of a metallic material, whereas layers 450a-450c may not be comprised of the metallic material. As such, and as will become discussed further, the resulting feature 400 that is formed by the cavity 250a that has the larger distance D1 may include a metallic material whereas the resulting feature 400 that is formed by the cavity 250b that has the smaller distance D2 may not include the metallic material.

Referring now to FIG. 9, a cross-sectional, side view of at least a portion of a component 100 during a manufacturing stage is provided, in accordance with an example embodiment. The component 100 can be manufactured by removing portions of the layers 450 that are applied on or above the masking layer 200. For example, the portions of each of the layers 450 that are on or above the masking layer 200 can be removed with an etching process. In various examples, and as depicted in FIG. 9, the portions of the layers 450 that are positioned within the cavity 250 remain within the cavity 250 after the portions that are on or above the masking layer 200 are removed.

Referring now to FIG. 10, a cross-sectional, side view of at least a portion of a component 100 during a manufacturing stage is provided, in accordance with an example embodiment. The component 100 can be manufactured by removing the masking layer 200 with a liftoff process. For example, the masking layer 200 can be removed with a chemical liftoff process, such as a chemical lift-off lithography process. After the masking layer 200 is removed, at least one feature 400 remains on the substrate 300. For example, the first layer 450a, the second layer 450b, and any subsequent layers 450 that remain on the substrate 300 may collectively define the feature on the substrate 300.

In various examples, the masking layer 200 is not completely or partially removed and becomes a portion of the component 100. For example, the masking layer 200 can be manufactured from a material, such as SiO2, and at least a portion of the masking layer 200 can remain on the component 100 as a layer 450 of the component 100. As such, the masking layer 200 may be a “leave-on” masking layer 200 that becomes at least a portion of interstitial cladding of the component 100. In various examples, the masking layer 200 is manufactured from the same material as the first layer 450a, such as SiO2, and at least a portion of the masking layer 200 and a portion of the first layer 450a remain on the component 100 and are not removed.

Incorporating the masking layer 200 as a layer 450 of the component has various benefits. For example, As the cavity 250 is almost fully filled with at least a first layer 450a, a different material may be used for the final layers 450. This may enable features with high, or extremely high, aspect ratios because the final layer 450, which would remain as a layer 450 of the component, could have a width of less than 1 nm.

Referring now to FIG. 11, a cross-sectional, side view of at least a portion of a component 100 during a manufacturing stage is provided, in accordance with an example embodiment. The component 100 can be manufactured by removing at least a vertical portion 452 (FIG. 10) of at least one of the layers 450, such as the second layer 450b. In various examples, the vertical portions 452 of at least some of the layers 450, such as all or some of the even layers 450 (e.g., the second and fourth layers 450), that remain within the cavities can be removed. For example, the vertical portions 452 of at least some of the layers 450 can be removed with an etching process, such as a chemical etching process. After the removal of at least some of the vertical portions 452 of the layers 450, lateral portions 454 of the other layers 450 may remain within the cavity 250 to provide physical support to the other layers 450 that are positioned above. The layers 450 that remain may collectively define the at least one feature 400. The vertical portions 452 of the layers 450 that remain may each define sub-features 401. Gaps 460 may be defined between each of the sub features 400 where some of the other layers 450 were removed. The size of each gap 460 can correspond to a thickness of the layer 450 that was removed to form the gap 460. In various examples, at least one of the gaps 460 is less than 50 nm thick, such as less than 30 nm thick, such as less than 10 nm thick.

Referring now to FIG. 12, a flow chart for a method 600 of forming at least one feature 400 on a substrate 300 of a component 100 of an electrical and/or optical device is provided, in accordance with an example embodiment. The method 600 can include a step 602 of applying a masking layer 200 on a substrate 300. The masking layer 200, once applied, may define at least one cavity 250 that is positioned between portions of the masking layer 200.

The method 600 can include a step 604 of applying a first layer 450a of a first material on the masking layer 200. The first layer 450a may also be applied to a portion of the substrate 300 that defines the cavity 250. The method 600 can include a step 606 of applying a second layer 450b of a second material on the first layer 450a. The second material can be different than the first material. Also, a first reflective index of the first material can be different than a first reflective index of the second material. In various examples, the thickness of the first layer 450a is different than the thickness of the second layer 450b by at least five percent. In various examples, the thickness of the first layer 450a is substantially the same as (e.g., within five percent) than the thickness of the second layer 450b. In various examples, at least one additional layer 450 is applied onto the second layer 450b, for example, one, two, three, five, seven, fifteen or more additional layers 450 are applied onto the second layer 450b. At least one of the additional layers 450 can include the first material or the second material. In various examples, at least one of the additional layers 450 includes the first material and at least another one of the additional layers 450 includes the second material. In various examples, at least one of the additional layers 450 includes a third material that has a refractive index that is different than the refractive index of the first material and the second material. In various examples, the component 100 includes at least four layers 450 and at least four of the layers 450, such as at least four and up to twenty of the layers 450, includes different materials.

The method 600 can include a step 608 of removing a first portion of the first layer 450a and a first portion of the second layer 450b with an etching process. The first portion of the first layer 450a and the first portion of the second layer 450b can be a portion of the respective layer 450 that is on or above the masking layer 200. The method can include a step of removing the masking layer 200 with a liftoff process. In various examples, the method does not include the step of removing the masking layer 200.

In various examples, the method includes a step of removing a vertical portion 452 of the second portion of the second layer 450b that is positioned within the cavity 250 after removing the first portion of the first layer 450a and the first portion of the second layer 450b with the etching process. In various examples, the method does not include a step of removing a vertical portion 452 of the second portion of the second layer 450b that is positioned within the cavity 250 after removing the first portion of the first layer 450a and the first portion of the second layer 450b with the etching process.

The method of manufacturing the component 100 and the resulting component 100, according to the various example embodiments provided herein, have various benefits. For example, the at least one feature 400 formed on the substrate 300 of the component 100 can be formed at a very high resolution. In various examples, the layers 450 are formed on the substrate 300 with an ALD process, which is a deposition technique that applies the layers 450 at an atomic level. As such, the resolution of the layers 450 and resulting features 400 of the component 100 may be less than 1 nm, which may be desirable and may not be achievable with conventional methods.

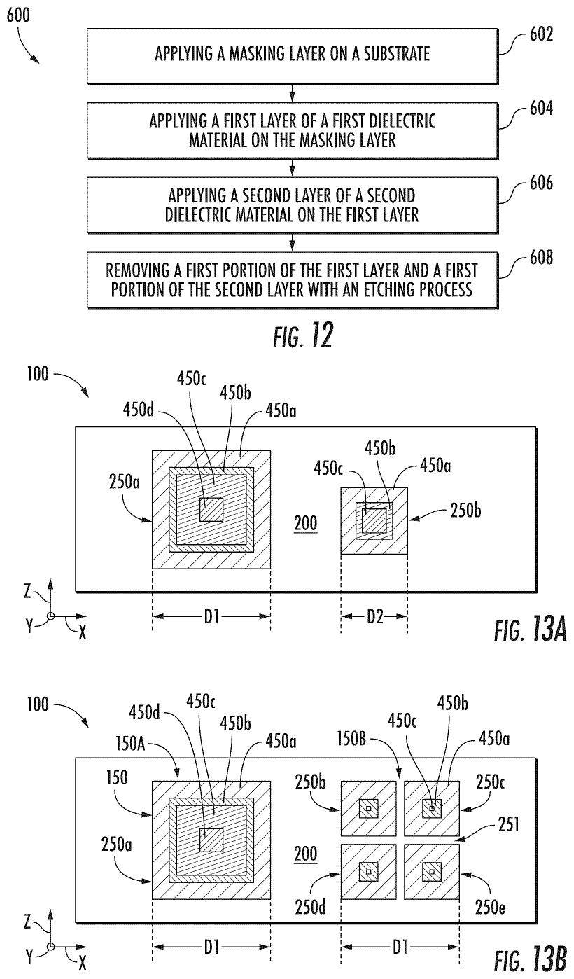

Referring now back to FIG. 8B and also to FIG. 13A, which provides a top view of at least a portion of the component of FIG. 8B during a subsequent manufacturing stage is provided, in accordance with an example embodiment. More specifically, FIG. 13A depicts the component of FIG. 8B after the step 608 of removing a first portion of the first layer 450a and a first portion of the second layer 450b with an etching process. As discussed, at least one cavity 250a can define a distance D1 that is different than a distance D2 of another cavity 250b (i.e., at least one cavity 250a can be a different size than another cavity 250b) and/or at least one cavity 250 can define a different shape than at least another cavity 250. As also previously discussed, this configuration of different sized cavities may result in at least one cavity 250a that has at least one additional layer 450, such as at least two or more additional layers, than at least another cavity 250b. For example, the larger cavity 250a of FIG. 13A includes layer 450d whereas the smaller cavity 250b does not.

Referring now to FIG. 13B, a top view of at least a portion of a component 100 is provided, in accordance with an example embodiment. More specifically, FIG. 13B depicts a component after the step 608 of removing a first portion of the first layer 450a and a first portion of the second layer 450b with an etching process. As discussed, at least one cavity 250a can define a distance D1. In various examples, a plurality of cavities 250, and the resulting features 400, may also define a distance D1. For example, the component 100 can define a plurality of areas 150, such as at least a first area 150a and a second area 150b, each area 150 having the same size (e.g., the same lateral area). At least one area 150b may, however, comprise a different quantity of cavities 250 than another area 150a. For example, at least a first area 150a may define only one cavity 250 and, subsequently, only one feature 400 is formed in the first area 150a; at least a second area 150b may define two or more cavities 250, such as three or more cavities 250, such as four or more cavities 250, and subsequently, a plurality of features 400 are formed in the second area 150b.

Various combinations of the number of cavities 250 (and the number of features 400) for the first area 150a, the second area 150b, and any additional areas 150 are contemplated. For example, at least one area 150 may have less than 5 cavities, such as less than 3 cavities, such as 1 cavity, whereas another area 150 may have at least 5 cavities, such as at least 10 cavities, such as at least 50 cavities, such as at least 100 cavities, such as at least 200 cavities.

In the example of FIG. 13B, the component 100 includes a first area 150a having only one cavity 250a and a second area 150b having four cavities 250b, 250c, 250d, and 250e. As can be seen in FIG. 13B, each area 150a, 150b has the same size (e.g., the same lateral area). As such, the volumes of the layers 450 within the respective one or more cavities 250 of each area 150a, 150b are similar. More specifically, the volume of the layers 450 within the cavity 250a of the first area 150a is the same as the summation of the volume of the walls 251 between the plurality of cavities 250b-250d and the volume of the layers 450 within each cavity 250b-250e. As such, this configuration may result in a feature 400 in a first area 150a having a substantially similar collective volume as a plurality of features 400 in a second area 150b, each area 150 having the same size.

In various examples, a ratio between the total volume of the layers 450 within a first area 150a and the total volume of the layers 450 within a second area 150b is at least 30:29 and up to 30:15, such as at least 30:29 and up to 30:25, where each area has the same size and where each area defines a different quantity of cavities 250. This configuration may have various benefits. For example, this configuration may result in features 400 within a certain area 150a having the same collective lateral area and a similar (but not the same) collective volume as the features 400 of another area 150b, but the features within each area 150a, 150b may differ regarding the quantity and/or materials of the layers 450 within the respective feature(s) of their respective area 150a,b, which may be beneficial.

Referring now to FIG. 14, a top view of at least a portion of a component 100 after step 602 of applying a masking layer 200 on a substrate 300 is provided, in accordance with various example embodiments. As discussed, the shape of each cavity 250 can have any shape. For example, and as depicted in FIG. 14, the at least one cavity 250 can have a chiral shape such that the shape is asymmetric. In various examples, the shape of at least one cavity 250 is triangular shaped with two curved sides that extend in the same direction.

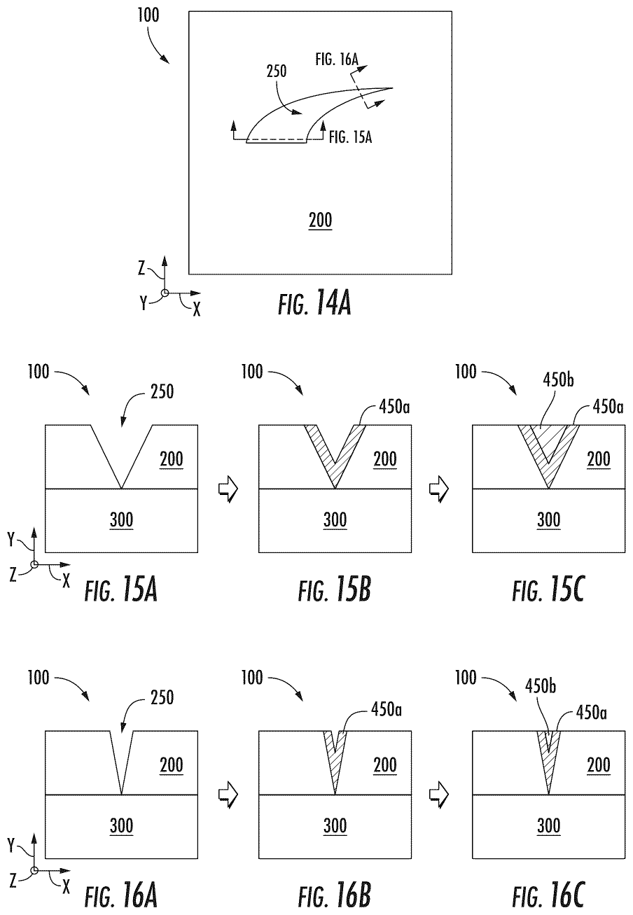

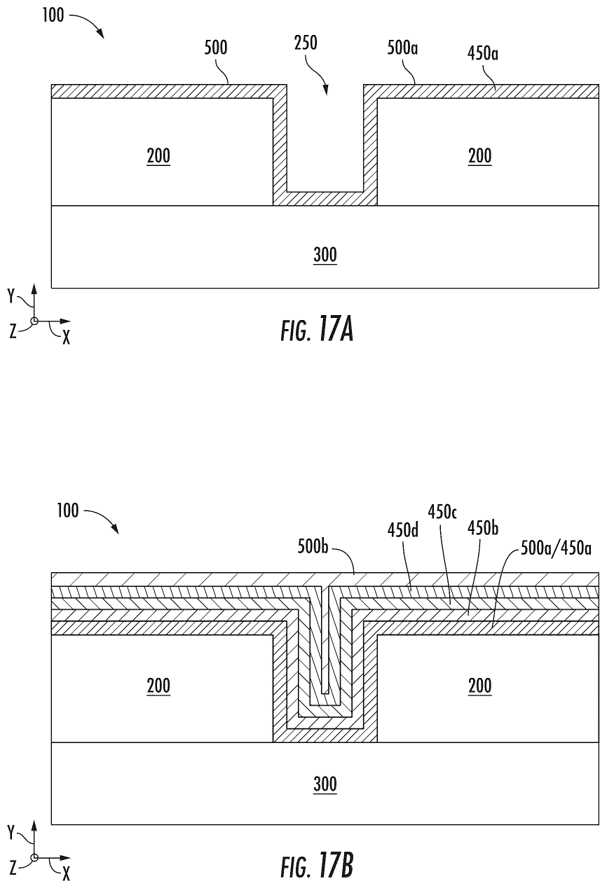

Referring now to FIGS. 15A and 16A, cross-sectional side views of a portion of the component 100 of FIG. 14A are provided. As best seen in these views, portions of the cavity 250 may be wider than other portions of the cavity 250. As depicted in FIGS. 15B-C and 16B-C, one or more layers 450, such as a first layer 450a and a second layer 450b can be applied to the masking layer 200 and at least partially fill the cavity 250. However, because portions of the cavity 250 are wider than other portions of the cavity 250, the result is a shape formed in the second layer 450b that narrows and moves upwards in the plane as the lithographic profile narrows. The resulting shape is a partial chiral-type shape. The resulting chiral shapes are challenging to fabricate using conventional methods and usually require multiple lithographic layers or 3D lithography. As such, the methods of the present disclosure provides a manufacturing process to fabricate features 400 that have a chiral shape that costs less and/or is less time consuming than conventional methods of manufacturing a chiral shaped feature.

Referring now to FIGS. 17A and 17B, cross-sectional, side views of at least a portion of a component 100 during different manufacturing stages are provided, in accordance with an example embodiment. The component 100 of FIGS. 17A and 17B can be manufactured similarly as the components 100 as described in reference to FIGS. 1-11 and 13A-17. However, in various examples, including the example depicted in FIGS. 17A-17B, the first layer 450 can be a first contact layer 500a that is applied on the masking layer 200. The first contact layer 500a may also be applied on a portion of the substrate 300. For example, the first contact layer 500a may be applied to the at least one portion of the substrate 300 that partially defines the at least one cavity 250.

In various examples, the at least one contact layer 500 is a transparent conducting film (TCF). The transparent conducting film can be an optically transparent and electrically conductive material. For example, the at least one contact layer may comprise indium tin oxide (ITO), transparent conductive oxides (TCO), conductive polymers, fluorine doped tin oxide (FTO), niobium doped anatase TiO2 (NTO), doped zinc oxide, graphene, or a combination thereof.

In various examples, the component 100 can be an active component. For example, the component 100 may be a light emitter (e.g., light emitting diode (LED), laser), a modulator (e.g., a modulator to modify the optical properties of light passing through the component 100), or a detector (e.g., a photodetector or a photovoltaic generation device). The at least one contact layer 500 can be configured to allow electrical contact with optically active material, such as the one or more layers 450. In various examples, the at least one contact layer 500 can include a photo-active material. The at least one contact layer 500 can include a semiconductor material. For example, the at least one contact layer 500 can include a semiconductor with a bandgap in an appropriate range, such as a III-V compound semi-conductor. For example, the at least one contact layer 500 may be, or include, an alloy that contains elements from both groups III and V in the periodic table. In various examples, the at least one contact layer 500 is, or includes, gallium nitride (GaN), gallium arsenide (GaAs), indium nitride (InN), indium phosphide (InP), indium arsenide (InAs), indium antimonide (InSb), or a combination thereof.

One or more layers 450 can be applied on the first contact layer 500a, as depicted in FIG. 17B. A second contact layer 500b can be applied on the one or more layers 450. In various examples, the second contact layer 500b is the uppermost contact layer. Manufacturing the component 100 of FIGS. 17A and 17B can include the step 608 of removing first portions of the contact layer 500 and plurality of layers 450 that are on or above the masking layer 200, as previously described. Manufacturing the component 100 of FIGS. 17A and 17B can include removing vertical portions 452 of at least some of the layer 450 that are positioned within the cavity 250, as also previously described.

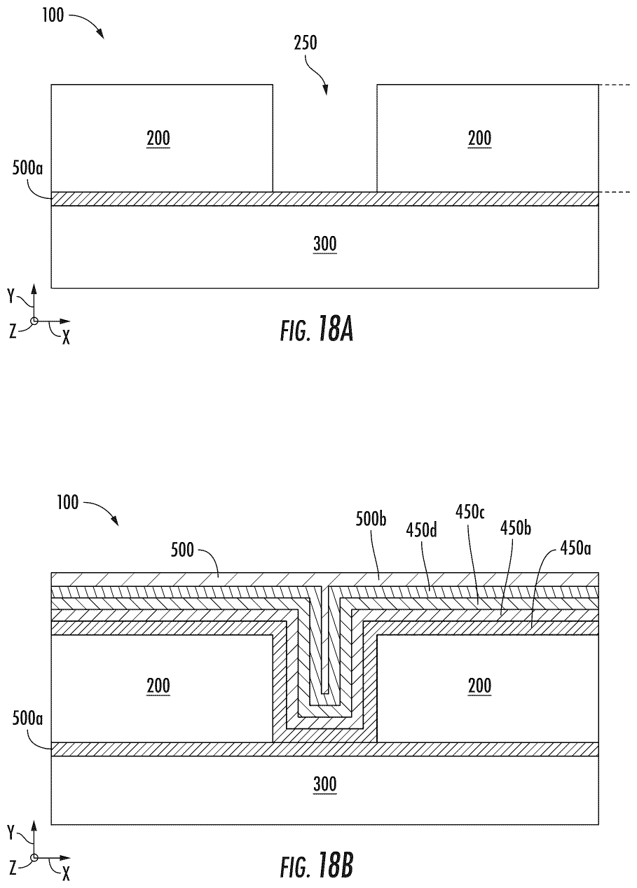

Referring now to FIGS. 18A and 18B, cross-sectional, side views of at least a portion of a component 100 during different manufacturing stages are provided, in accordance with an example embodiment. The component 100 of FIGS. 18A and 18B can be manufactured similarly as the component 100 of FIGS. 17A and 17B. However, at least in the example of FIGS. 18A and 18B, a first contact layer 500a may be applied on the substrate 300 and the masking layer 200 can be applied on the first contact layer 500a.

Applying a contact layer 500 has various benefits. For example, microstructures and/or nanostructures that emit or detect light are difficult to efficiently contact electrically. As such, applying a contact layer 500 that is electrically conductive is sometime desired. However, applying a contact layer 500 is difficult using conventional methods. As such, applying at least one contact layer 500 with the methods described herein, may be more cost effective or less time consuming than conventional methods.

In various examples, the aspect ratio of the resulting features 400 or sub-features 401 can be formed such that the feature or sub-features 401 have a high aspect ratio (e.g., H:W ratio that is greater than 1:1). For example, at least one of the layers 450 can be thinly applied (e.g., thickness of less than 5 nm, such as less than 2 nm) and the masking layer 200 may be relatively thick (e.g., at least 5 nm, such as at least 10 nm). Subsequently, the adjacent layers 450 may be selectively removed, which may produce a sub-feature that has a width of less than 5 nm, such as less than 2 nm, but has a height of at least 5 nm, such as at least 10 nm. A high aspect ratio of the resulting feature or sub-feature may be desirable and may not be achievable with conventional methods.

In various examples, different materials may be used for at least some of the layers 450. As such, a desired material property, such as a refractive index, for at least a region of the resulting feature can be tailored by adjusting the thickness of the layers 450 based at least in part on the material property of the materials used for each of the layers 450. Achieving some desired material properties, such as refractive indexes, may not be achievable using conventional methods. As such, the component 100 and method of the present disclosure may have the benefit of achieving desired material properties, such as refractive indexes, for at least some regions of the feature.

### CONCLUSION

The above descriptions of various embodiments of the subject disclosure and corresponding figures and what is described in the Abstract, are described herein for illustrative purposes, and are not intended to be exhaustive or to limit the disclosed embodiments to the precise forms disclosed. It is to be understood that one of ordinary skill in the art may recognize that other embodiments having modifications, permutations, combinations, and additions can be implemented for performing the same, similar, alternative, or substitute functions of the disclosed subject matter, and are therefore considered within the scope of this disclosure. Therefore, the disclosed subject matter should not be limited to any single embodiment described herein, but rather should be construed in breadth and scope in accordance with the appended claims below. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A method of forming at least one feature on a substrate of a component for an electrical and/or optical device, the method comprising:
forming at least one cavity in a masking layer on the substrate, wherein the at least one cavity is positioned between portions of the masking layer;
applying a first layer of a first material on the masking layer, wherein the first layer is deposited on a bottom of the at least one cavity;
applying a second layer of a second material on the first layer, wherein the second layer is deposited on the first layer within the at least one cavity; and
removing a first portion of the first layer and a first portion of the second layer with an etching process, wherein the first portion of the first layer and the first portion of the second layer are disposed outside of the at least one cavity.

2. The method of claim 1, further comprising removing the masking layer with an etching process.

3. The method of claim 1, further comprising:
applying the first layer of the first material on the masking layer and on a portion of the substrate.

4. The method of claim 1, wherein at least a second portion of the first layer and a second portion of the second layer is positioned within the cavity after removing the first portion of the first layer and the first portion of the second layer with the etching process.

5. The method of claim 4, further comprising removing a vertical portion of the second portion of the second layer that is positioned within the cavity after removing the first portion of the first layer and the first portion of the second layer with the etching process.

6. The method of claim 5, wherein at least a lateral portion of the second portion of the second layer is positioned on the first layer after removing the vertical portion of the second portion of the second layer.

7. The method of claim 1, wherein applying the first layer of the first material on the masking layer and applying the second layer of the second material on the masking layer is performed with a chemical vapor deposition (CVD) process.

8. The method of claim 7, wherein the CVD process is an atomic layer deposition (ALD) process.

9. The method of claim 1, wherein applying the first layer of the first material on the masking layer and applying the second layer of the second material on the masking layer is performed with a physical vapor deposition (PVD) process.

10. The method of claim 1, wherein each of the at least one cavity defines a height (H) and a width (W), wherein a ratio (H:W) between the height (H) and the width (W) of each of the at least one cavity is at least 1:1.

11. The method of claim 10, wherein the method comprises forming a plurality of cavities in the masking layer on the substrate, and wherein a width (W) of at least one of the plurality of cavities is different than a width (W) of another one of the plurality of cavities.

12. The method of claim 1, wherein the first layer has a first thickness and the second layer has a second thickness, and wherein the first thickness is different than the second thickness by at least five percent.

13. The method of claim 1, further comprising:
applying a third layer of a third material on the second layer.

14. The method of claim 13, further comprising:
applying a fourth layer of a fourth material on the third layer.

15. The method of claim 1, further comprising:
applying a third layer of the first material on the second layer; and
applying a fourth layer of the second material on the third layer,
wherein the first layer has a first thickness, the second layer has a second thickness, the third layer has a third thickness, and the fourth layer has a fourth thickness.

16. The method of claim 15, wherein the first thickness, the second thickness, the third thickness, and the fourth thickness are each different than the other thicknesses by at least five percent.

17. The method of claim 15, wherein:
the first thickness and the third thickness are within five percent of each other,
the second thickness and the fourth thickness are within five percent of each other, and
the first thickness is different than the second thickness by at least five percent.

18. The method of claim 1, further comprising:
applying a third layer of the first material or a third material on the second layer; and
applying a fourth layer of the second material or a fourth material on the third layer,
wherein the first layer, the second layer, the third layer, and the fourth layer define a refractive index profile that either decreases or increases as the layers are applied.

19. The method of claim 1, wherein the first layer is a first contact layer that comprises an optically transparent and electrically conductive material.

20. The method of claim 1, wherein a cavity of the at least one cavity has a chiral shape.
